(19) United States
(12) Patent Application Publication
(10) Pub. No.: US 2006/0231745 A1
(43) Pub. Date: Oct. 19, 2006

(54) Method and circuit arrangement for driving light-emitting diodes

(75) Inventors: Emanuele Bodano, Padova (IT); Michael Lenz, Zorneding (DE)

Correspondence Address: Maginot, Moore & Beck;Chase Tower, Suite 3250, 111 Monument Circle, Indianapolis, IN, 46204, US

(73) Assignee: Infineon Technologies AG, Muenchen (DE)

(21) Appl. No.: 11/384,038

(22) Filed: Mar. 17, 2006

(30) Foreign Application Priority Data
Mar. 18, 2005 (DE) 10 2005012625.1

(51) Int. Cl. H01J 40/14; H03K 17/78

(52) U.S. Cl. 250/214 R; 250/214 SW

(57) ABSTRACT

A circuit arrangement includes a first switch device and at least a second switch device. The first switch device is operably coupled to alternately switch on and off a first operating current to a first light-emitting diode arrangement such that the first light-emitting diode arrangement has a first brightness. The second switch device is operably coupled to alternately switch on and off a second operating current to a second light-emitting diode arrangement such that the second light-emitting diode arrangement has a second brightness. The circuit arrangement further includes a logic device configured to control the first and second switch devices that the first and second switch devices do not both switch on simultaneously.

### TECHNICAL FIELD

The disclosure relates to a circuit arrangement for simultaneously operating a first light-emitting diode arrangement and at least one further light-emitting diode arrangement, and to a method for simultaneously operating a first light-emitting diode arrangement and at least one further light-emitting diode arrangement.

### BACKGROUND

Light-emitting diodes (LEDs) are of interest as luminous means for more and more applications. In particular, light-emitting diodes are used instead of incandescent bulbs in the automotive sector. This became possible because light-emitting diodes have more recently obtained a brightness that is comparable to conventional luminous means. Light-emitting diodes are now used even in preference to the conventional luminous means since they are more cost-effective, can be produced with virtually any arbitrary geometry and, moreover have a lower energy consumption for the same brightness relative to the conventional luminous elements.

In automotive applications, in particular, it is necessary in many cases to adapt the brightness of the luminous means, in particular of the light-emitting diodes or light-emitting diode arrangements used, to the respective ambient light conditions, or to enable a corresponding adaptation. Since the current consumption and corresponding power loss increases with each new generation of super-bright light-emitting diodes, it is necessary to limit not only the brightness, but also the maximum current consumption according to the respective application.

In order to set or regulate the brightness with which a light-emitting diode or a light-emitting diode arrangement is luminous, and in order to limit the current consumption, it is known from the prior art to connect a non-reactive series resistor upstream of the light-emitting diode or the light-emitting diode arrangement. This solution has the disadvantages of a high power loss and an operating current dependent on the operating voltage.

In order to regulate the brightness and in order to reduce the power loss, the operating current of light-emitting diodes or of light-emitting diode arrangements is regularly pulse-width-modulated according to the prior art.

A pulse-width modulated operating current can be realized for example by means of a switch which is connected in series with the non-reactive series resistor and is correspondingly opened and closed again. However, the problems of a high power loss and an operating current dependent on the operating voltage cannot be completely eliminated with this embodiment.

An analogously regulated current source which provides the operating current for the light-emitting diode or the light-emitting diode arrangement is often used according to the prior art. The power loss resulting from the product of the difference between the operating voltage and the diode voltage and the diode current is also high in the case of a circuit arrangement of this type.

In order to reduce the power loss (in conjunction with, if appropriate, at the same time regulability/setability of the brightness), it is known to connect a step-down converter (also called buck converter) upstream of each light-emitting diode or each light-emitting diode arrangement comprising a plurality of light-emitting diodes. Such a step-down converter generally comprises a switch in the form of a transistor, a freewheeling diode connected in series therewith, and a (generally external) inductor coil arranged at the node between the switch and freewheeling diode. The transistor operating as a switch is switched on and off by means of a pulse-width modulated control voltage at a high frequency (regularly at 20 kHz to a few MHz). The mean output current representing the operating current for the light-emitting diode or light-emitting diode arrangement is determined, in continuous operation of the step-down regulator, essentially by the quotient of switch-on time to period duration, the duty ratio or duty factor.

This embodiment variant satisfactorily solves the above-mentioned problems. However, since such a circuit arrangement with a step-down converter connected upstream of each light-emitting diode or each light-emitting diode arrangement comprising a plurality of light-emitting diodes requires inductor coils for each step-down converter, however, this circuit arrangement is comparatively expensive and is therefore rarely used.

There is a need, therefore, for a circuit arrangement and also a method which cost-effectively permits operation of light-emitting diode arrangements at a predetermined brightness.

### SUMMARY

The above described need, as well as others, is achieved by at least some embodiments of the invention.

A first embodiment of the invention is a circuit arrangement having a first switch device. The first switch device is operably coupled to alternately switch on and off a first operating current to a first light-emitting diode arrangement such that the first light-emitting diode arrangement has a first brightness. The circuit arrangement also includes at least a second switch device operably coupled to alternately switch on and off a second operating current to a second light-emitting diode arrangement such that the second light-emitting diode arrangement has a second brightness. The circuit arrangement further includes a logic device configured to control the first and second switch devices that the first and second switch devices do not both switch on simultaneously.

A second embodiment of the invention is a method for operating a first light-emitting diode arrangement and a second light-emitting diode arrangement. The method includes a step of alternately switching on and off a first operating current for the first light-emitting diode arrangement such that the first light-emitting diode arrangement has a first predetermined brightness. The method also includes alternately switching on and off at least a second operating current for at least a second light-emitting diode arrangement such that the second light-emitting diode arrangement has a second predetermined brightness. The first and the second light-emitting diode arrangements are not switched on simultaneously.

The above described features and advantages, as well as others, will become more readily apparent to those of ordinary skill in the art by reference to the following detailed description and accompanying drawings.

### BRIEF DESCRIPTION OF THE DRAWINGS

FIG. 1: shows a basic circuit diagram of a first exemplary embodiment of a circuit arrangement according to the invention based on a step-down regulator as total operating current source for all of the connected light-emitting diodes;

FIG. 2: shows a circuit diagram of the exemplary embodiment of the circuit arrangement according to the invention according to FIG. 1 of a first possible embodiment of the step-down regulator;

FIG. 3: shows control signals in the step-down regulator according to FIG. 2;

FIG. 4: shows control signals in the circuit arrangement according to FIGS. 1 and 2;

FIG. 5: shows a basic circuit diagram of a second exemplary embodiment of a circuit arrangement according to the invention based on a step-down regulator as total operating current source for all of the connected light-emitting diodes and with an error identification circuit for identifying overvoltages and undervoltages.

### DETAILED DESCRIPTION

Embodiments of the invention ares based on a method for simultaneously operating a first light-emitting diode arrangement and at least one further light-emitting diode arrangement, in which a first operating current for the first light-emitting diode arrangement is alternately switched on and off in such a way that the first light-emitting diode arrangement is luminous with a first predeterminable or predetermined brightness, and in which a further operating current for the at least one further light-emitting diode arrangement is likewise alternately switched on and off in such a way that the at least one further light-emitting diode arrangement is luminous with a further predeterminable or predetermined brightness. In this case “a” brightness is understood not to mean a lighting up and extinguishing perceived as flashing, but rather a continuous luminousness with an essentially unchanging intensity.

It goes without saying to a person skilled in the art that the first light-emitting diode arrangement and/or the at least one light-emitting diode arrangement may be or may comprise in each case a single light-emitting diode or a parallel circuit formed by a plurality of light-emitting diodes and/or a series circuit formed by a plurality of light-emitting diodes.

At least some embodiments are based on the insight that the total operating current consumption of all of the simultaneously operated light-emitting diode arrangements (light-emitting diodes or light-emitting diode groups) is particularly large when it is necessary to provide the operating current for all of the light-emitting diode arrangements simultaneously. This necessitates the fact that either a current source that alone provides the total operating current for the light-emitting diode arrangements has to be embodied with correspondingly large dimensioning or that as has already been explained above a multiplicity of individual current sources assigned to the different light-emitting diodes or light-emitting diode groups have to be provided. Both solutions are comparatively expensive.

Therefore, the above described embodiments provide for the different light-emitting diodes or light-emitting diode groups to be driven in such a way that all the operating currents of all of the light-emitting diode arrangements are not or have not been switched on simultaneously. A current source that provides the total operating current may then have a lower rated power consumption or a plurality of light-emitting diodes or light-emitting diode groups may be combined into groups driven by the same current source.

An inductance is generally required for realizing a current source. The advantage of the invention is: only one (relatively expensive) inductance is required for driving a plurality of light-emitting diode arrangements.

In terms of circuitry, the method according to embodiments of the invention can be realized by way of example as follows: The circuit arrangement for simultaneously operating a first light-emitting diode arrangement and at least one further light-emitting diode arrangement according to the invention comprises a first switching device in order to alternately switch on and off a first operating current for the first light-emitting diode arrangement in such a way that the first light-emitting diode arrangement is luminous with a first predeterminable or predetermined brightness. For operating the at least one further light-emitting diode arrangement, the circuit arrangement comprises a corresponding further switching device. This further switching device is provided for likewise alternately switching on and off the further operating current for the at least one further light-emitting diode arrangement in such a way that the at least one further light-emitting diode arrangement is luminous with a further predeterminable or predetermined brightness.

The first switching device and/or the at least one further switching device may be formed, e.g. by a transistor, in particular a bipolar transistor or a field effect transistor.

According to such embodiments, a logic device is now provided in order to drive the switching devices in such a way that all of the light-emitting diode arrangements do not simultaneously switch on or have not simultaneously switched on the respective operating current for the corresponding light-emitting diode arrangement.

The above explanations relate to substantially inhibiting and/or preventing all of the light-emitting diodes or light-emitting diode arrangements from simultaneously having applied to them their operating current that is respectively required in order to obtain the desired brightness. A simultaneous application of operating current to a plurality of light-emitting diode arrangements is not precluded in principle.

If the maximum instantaneous current or power consumption is minimized, the components that provide the operating current may have a comparatively low rated power and/or the number of components required may be reduced compared with arrangements that are customary at the present time. Both measures have a cost-lowering effect.

The maximum instantaneous current or power consumption can be minimized by preventing the operating currents of two or more light-emitting diode arrangements from being or having been switched on simultaneously.

In terms of circuitry, this is realized according to the invention by enabling the logic device to drive the switching devices in such a way that two or more light-emitting diode arrangements do not simultaneously switch on or have not simultaneously switched on the respective operating current for the corresponding light-emitting diode arrangement.

For reasons of simplicity and the least outlay for ensuring a time-invariant setability of the brightness, the invention provides for the operating currents of the light-emitting diode arrangements to be switched on in a periodic clock. The invention therefore preferably provides for the logic device to be designed for a driving of the switching devices in a periodic clock.

For the same reasons, it is expedient for the operating currents of the light-emitting diode arrangements to be switched on and off again in a predetermined or predeterminable mark-space ratio or duty ratio. In a particularly advantageous embodiment variant of the invention, therefore, the logic device is designed for a driving of the switching devices with a predetermined or predeterminable mark-space ratio.

In this application, predetermined and predeterminable shall be interpreted interchangeably.

As has already been explained in detail above, it is favorable for cost reasons if a single (total-operating) current source that provides a total operating current for the first and the at least one further light-emitting diode arrangement is present.

An appropriate current source to which consideration is given is, in particular, one which supplies a current that is constant on average at least in order to ensure a temporally imperceptibly changing brightness of the light-emitting diode arrangements.

It has proved to be very favorable if the output current provided by the current source, that is to say the total operating current, can be preset and/or regulated. Such an intervention enables a presetting and/or regulation of the basic brightness of all of the light-emitting diode arrangements that are supplied with an operating current via the current source.

A further flexibility is achieved if the total operating current is, or can be dynamically adapted to the respective (instantaneous) current demand for the purpose of obtaining a predetermined or predeterminable brightness of the light-emitting diode arrangement respectively switched on or of the light-emitting diode arrangements respectively switched on. Different brightnesses can then be established, e.g. by means of dynamic changes in the (total) operating current provided by the current source, in the case of a plurality of identical light-emitting diode arrangements, even if the switch-on durations of the respective operating currents are chosen to be identical in magnitude (by the logic device).

A wide variety of types of current sources are taken into consideration for the realization of the circuit arrangement according to the invention. By way of example, a switched-mode power supply may be used as the current source. It is favorable to use a step-down converter or a step-up converter.

Embodiments of the invention furthermore provide for checking whether an error has occurred in one or a plurality of the light-emitting diode arrangements. Therefore, in one embodiment, the circuit arrangement according to the invention comprises an error identification circuit for identifying an error in at least one of the light-emitting diode arrangements.

From among the multiplicity of errors which can occur, it is expedient to ascertain whether a light-emitting diode or a light-emitting diode group is short-circuited e.g. because the relevant light-emitting diode is burnt out. Moreover, it is important to ascertain whether a light-emitting diode or a light-emitting diode group is or is not correctly connected.

The embodiments described above therefore provide for checking in at least one of the light-emitting diode arrangements to determine whether an overvoltage (open circuit as indication of an absent contact-connection) or an undervoltage (short circuit as indication of a destruction of the light-emitting diode) has occurred.

The circuit arrangement according to the embodiments of the invention therefore preferably comprises an overvoltage identification device for identifying an overvoltage in at least one of the light-emitting diode arrangements and/or an undervoltage identification device for identifying an undervoltage in at least one of the light-emitting diode arrangements.

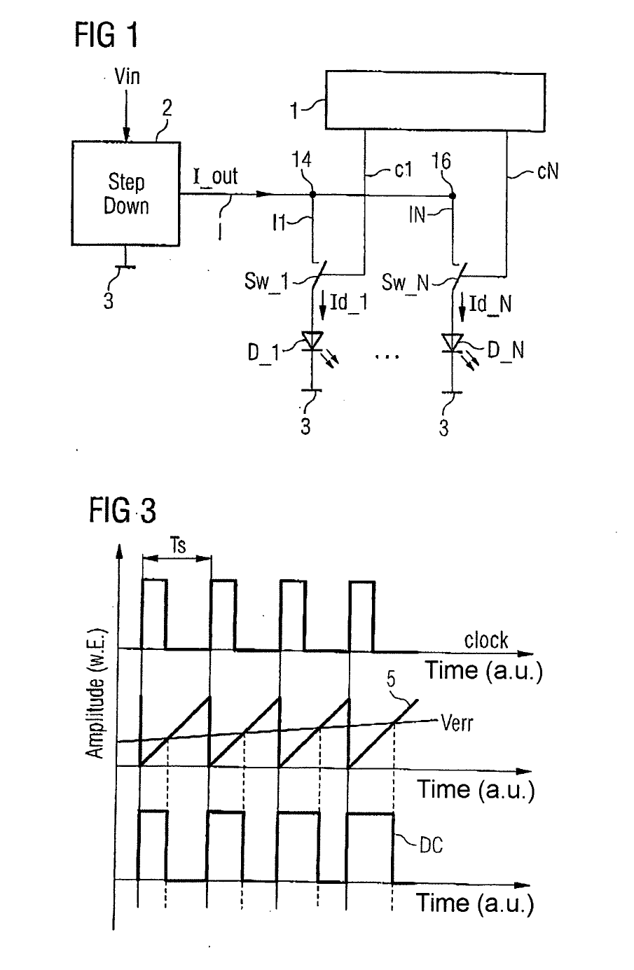

Referring now specifically to FIG. 1, the basic circuit diagram shown in FIG. 1 shows a circuit arrangement according to the invention comprising a single step-down converter, which provides an output current I_out, and comprising a logic circuit 1 in order to drive a number N of light-emitting diodes D_1, . . . D_N in the present exemplary embodiment.

The step-down converter 2 may be embodied in any desired manner. The principle of the step-down converter (or buck converter) is described for example in “Elektronik für Ingenieure” [Electronics for Engineers], by Ekbert Hering, Klaus Bressler, Jürgen Gutekunst, 3rd edition, Springer-Verlag, Berlin, Heidelberg, page 626 et seq.

An input voltage Vᵢₙ is fed to the step-down converter 2 on the input side. On the output side, the step-down converter 2 supplies an output current I_out, which is fed into a supply line l. In the present exemplary embodiment, the supply line l has a number N of branches that branch off from the nodes 14, 16. The number N of branches represent supply lines l1, . . . , lN via which the light-emitting diodes D_1, . . . D_N can be supplied with a respective operating current Id_1, . . . Id_N.

Each light-emitting diode D_1, . . . D_N can be isolated from the operating current supply effected via the supply lines l, l1, . . . lN by means of a switch Sw_1, . . . Sw_N connected upstream. In this case, the switch can be inserted upstream or downstream of the diode.

The logic circuit 1 has a number N of control outputs which are connected to corresponding control inputs of the switches Sw_1, . . . Sw_N via corresponding control lines c1, . . . cN. The switches Sw_1, . . . Sw_N can be opened and closed by means of a corresponding driving of the control inputs.

In the present exemplary embodiment, a constant output current I_out is set by means of the buck converter 2. The logic circuit 1 determines the switch-on time ton_1, . . . ton_N during which the various switches Sw_1, . . . Sw_N switch in the operating current Id_1 . . . Id_N of the various light-emitting diodes D_1, . . . D_N. In this case, the brightness of the individual light-emitting diodes D_1, . . . D_N is determined by the ratio between the time ton_1, . . . ton_N, during which a corresponding switch Sw_1, . . . Sw_N is switched on, and the time toff_1, . . . toff_N, during which the corresponding switch Sw_1, . . . Sw_N is switched off, and also the magnitude of the operating current Id_1, . . . Id_2 during the switch-on time ton_1, . . . ton_N.

According to embodiments of the invention, it is provided that the switches Sw_1, . . . Sw_N are not switched on at the same time. The mean operating current <Id_1>, . . . <Id_N> through the respective diode D_1, . . . D_N results from the ratio of the time duration ton_1, . . . ton_N, during which a respective switch Sw_1, . . . Sw_N is switched on, to the time duration ton_1+toff_1, . . . ton_N+toff_N until the corresponding switch Sw_1, . . . Sw_N is switched on again, multiplied by the corresponding output current I_out of the buck converter 2. By means of software and with the aid of the logic circuit 1, it is possible to alter the switch-on time to switch-off time ratio

$$\frac{ton\_ 1}{toff\_ 1} : \frac{ton\_N}{{toff\_N}^{′}}$$

referred to hereinafter as mark-space ratio, in order to precisely set the brightness of the corresponding light-emitting diodes D_l, . . . D_N.

In contrast to the solution in accordance with the prior art as described in the introduction to the description, the use of a buck converter for regulating the brightness of a light-emitting diode (or, if appropriate a group of light-emitting diodes), if said buck converter is used for driving a plurality of parallel-connected light-emitting diodes or light-emitting diode groups, does not constitute a high-price solution, so that its use possibilities have been significantly improved.

It goes without saying that, instead of a step-down regulator used in the present exemplary embodiment, it is also possible to use any other switched-mode power supply with, if appropriate, regulable output current. A step-up converter may also be used instead of the buck converter. The use of a buck converter constitutes an outstanding solution here because the efficiency of the entire system can thereby be significantly improved compared with other solutions.

The output current I_out of the buck converter 2 may be formed for example with the aid of an internal or external reference voltage or of an internal or external reference current, or by means of a digital command, as a fraction of an internal reference current or of an internal reference voltage.

Provision may furthermore be made for varying the output current I_out of the buck converter (or of the other circuit arrangement supplying the output current) in a manner corresponding to a switching on of one or more of the switches Sw_1, . . . Sw_N. The circuit arrangement according to FIG. 1 may for example also be supplemented by an error identification circuit 13, as illustrated, e.g. in FIG. 5. In the exemplary embodiment in accordance with FIG. 5, the error identification circuit 13 comprises two comparators 18, 19, which compare the voltage present in the supply line l relative to a reference potential 3 with two reference voltages HV, LV. One reference signal is an overvoltage reference signal HV and the other is an undervoltage reference signal LV.

If the voltage in the supply line l is greater than the overvoltage reference signal HV, then the comparator 18 outputs a signal OC (open circuit) indicating this exceeding. The overvoltage reference signal HV is chosen to be somewhat greater than the voltage drop affected by, the output current I_out across a respective branch l1, . . . lN with closed switch Sw_1, . . . Sw_N. If the actual voltage value across a branch l1, . . . lN with closed switch Sw_1, . . . Sw_N exceeds this predetermined overvoltage value HV, then this indicates that no or an excessively low current Id_1, . . . Id_N is flowing through the corresponding branch l1, . . . lN. In the first case in particular, this is an indication that the corresponding light-emitting diode D_1, . . . D_N in the branch l1, . . . lN is not contact-connected or has been destroyed.

In a similar manner, the undervoltage reference signal LV is chosen to be somewhat smaller than the voltage drop that is usually dropped across the corresponding branch l1, . . . lN with closed switch Sw_1, . . . Sw_N. If the voltage value in the supply line l with closed switch Sw_1, . . . Sw_N of a corresponding branch l1, . . . lN is lower than the predetermined undervoltage reference value LV, then the comparator 19 outputs a corresponding signal SC (short circuit). If the voltage of the supply line l is less than the undervoltage reference signal LV, this indicates that the relevant switched-in branch l1, . . . lN is completely or partly short-circuited.

If the instantaneous output signals OC, SC of the comparators 18, 19 are combined with the switch positions of the switches Sw_1, . . . Sw_N that are predetermined by the logic circuit 1 via the drive lines c1, . . . cN, then it is possible to ascertain in a simple manner in which of the branches l1, . . . lN a light-emitting diode D_1, . . . D_N is defective.

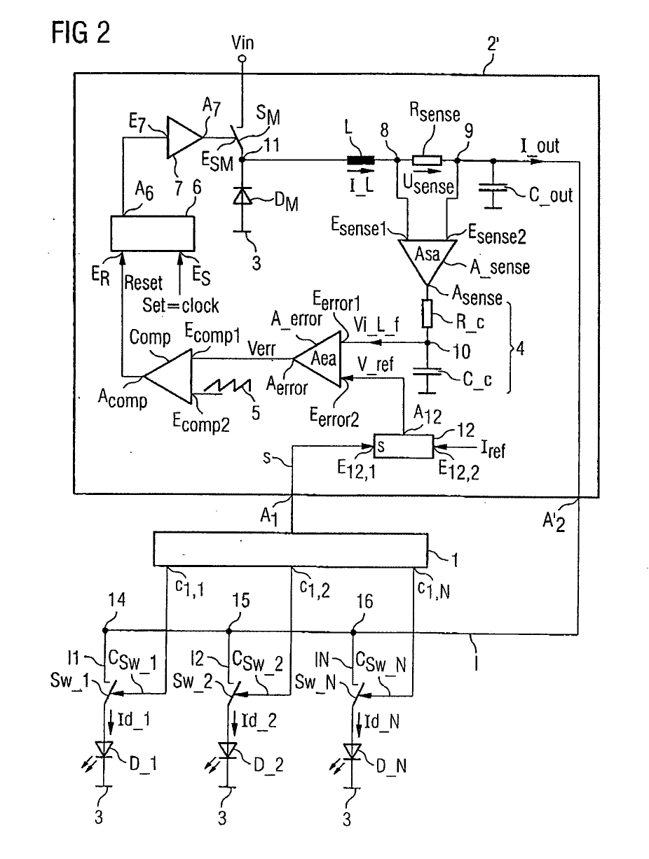

FIG. 2 reveals how it is possible to design a step-down regulator in a circuit arrangement of the type according to the invention.

The step-down regulator 2′ in accordance with FIG. 2 comprises as essential elements a main switch S_{M}, a freewheeling diode D_{M} and also an inductor coil L. The main switch S_{M} is connected in series with the freewheeling diode D_{M}. The input voltage Vᵢₙ can be applied to the outer terminals of this series circuit. An inductor coil L is connected to the node 11 between switch S_{M} and freewheeling diode D_{M}. A measuring resistor Rₛₑₙₛₑ is connected in series with the inductor coil L. The supply line l adjoins said measuring resistor Rₛₑₙₛₑ, which supply line branches in the manner described above into supply lines l1, l2, . . . lN for the N light-emitting diodes D_1, D_2, . . . D_N in the present exemplary embodiment. An output capacitance C_out connected to ground 3 is connected to the output node 9 of the measuring resistor Rₛₑₙₛₑ. The node 8 between the inductor coil L and the measuring resistor Rₛₑₙₛₑ is connected to a first input Eₛₑₙₛₑ₁ of a measuring amplifier A_{—sense}. The node 9 connecting the measuring resistor Rₛₑₙₛₑ to the supply line l is connected to a second input Eₛₑₙₛₑ₂ of the measuring amplifier A_{—sense}.

The output Aₛₑₙₛₑ of the measuring amplifier A_{—sense} is connected to a nonreactive resistor R_c, downstream of which a capacitor C_c connected to the reference ground potential 3 is connected in series via a node 10.

The node 10 is connected to a first input Eₑᵣᵣₒᵣ₁ of an error amplifier A_{—error}. The output Aₑᵣᵣₒᵣ of the error amplifier A_{—error} is connected to a first input E_{comp1} of a comparator Comp. The output A_{comp} of the comparator Comp is connected to a reset input E_{R} of a latch 6. The output A₆ of the latch 6 is connected to an input E₇ of a driver 7. The output A₇ of the driver 7 is connected to the control input E_{SM} of the main switch S_{M}.

The logic circuit 1—also illustrated in FIG. 2 of the drawings—as an essential constituent part of the invention has a selection output A₁ which is connected via a selection line S to a first input E_{12,1} of a selection circuit 12. The output A₁₂ of the selection circuit 12 is connected to a second input Eₑᵣᵣₒᵣ₂ of the error amplifier A_{—error}.

In the manner described above, the logic circuit 1 has control outputs C_{1,1}; C_{1,2}; . . . C_{1,N} connected to corresponding control inputs C_{SW-1}, C_{SW-2}, . . . C_{SW-N} of the switches Sw_1, Sw_2, . . . Sw_N connected upstream of the light-emitting diodes D_1, D_2, . . . D_N.

The function of the circuit arrangement according to FIG. 2 is revealed as follows:

If a customary rectangular pulse operation of the step-down converter 2′ is assumed, then the induction current I_L exhibits an essentially triangular-waveform profile. The profile of the induction current I_L is measured as measurement voltage Uₛₑₙₛₑ at the low-resistance measuring resistor Rₛₑₙₛₑ. In the present ex-emplary embodiment, the measurement voltage Uₛₑₙₛₑ is amplified with the gain factor Asa by the measuring amplifier A_{—sense} and filtered with the aid of the RC filter 4 comprising the nonreactive resistor R_c and the capacitance C_c. The amplified and filtered measurement signal Vi_L_f is proportional to the mean induction current <I_L>, as emerges from the equation specified below:
Vi_{—}L_{—}f=<I_{—}L*Rsense*Asa>=k*<I_{—}L>,
where the mean value is identified with the aid of the < > and k represents a constant value.

The filter output signal Vi_L_f is fed to the first input Eₑᵣᵣₒᵣ₁. The error amplifier A_{—error} outputs an error voltage signal Verr amplified with the gain factor Aea, which signal results from the difference between the filter output voltage Vi_L_f and the reference voltage V_ref.

The error signal Verr is then compared in the comparator Comp with an internal clocked sawtooth signal 5, which is derived from a rectangular-waveform clock signal clock in the present exemplary embodiment—as emerges from FIG. 3. If the sawtooth signal 5 is greater than the error signal Verr, then a logic “high” signal is present at the output A_{comp} of the comparator Comp. If the sawtooth signal 5 is less than the error signal Verr, then a logic “low” signal can be tapped off at the output A_{comp} of the comparator Comp.

The latch 6 is fed the abovementioned clock signal clock with rectangular amplitude as set signal via a set input Eₛ, on the one hand, and the comparator out-put signal A_{comp} as reset signal via its reset input E_{R} on the other hand. Through the rising edge of the clock signal clock, the output signal at the output A₆ of the latch 6 is brought to the “high” state. As soon as the signal at the output of the comparator Comp undergoes transition to the “high” state, that is to say as soon as the sawtooth signal is greater than the error signal Verr, the output signal A₆ brought to the “high state”, in the latch 6 by means of the clock signal clock is reset to the “low” state. As a result, a periodic rectangular signal DC that is pulse-width-modulated, if appropriate arises at the output A₆ of the latch 6 (cf. FIG. 3).

Said rectangular signal DC is conditioned in the driver 7 for the driving of the main switch S_{M}. Each “high” state of the pulse-width-modulated signal DC conditioned in the driver 7 closes the switch S_{M}, and each “low” state of the signal DC opens the switch S_{M}. These switching operations determine the current I_L in the inductance L.

The greater the gain Aea of the error amplifier A_error the more precisely the mean induction current <I_L> can be set. The following results for an error signal going towards zero Verr>0:
V_{ref}=k*<I_{—}L>

Note: the reference voltage signal V_{ref} may also be derived from a reference current reference_current e.g. according to the following equation:
V_{ref}=f(reference_current)=α*reference_current
where α results from the driving by the logic circuit 1 via the selection circuit 12. The unit of α is volt/ampere.

An output current I_out smoothed by the output capacitance C_out can now be tapped off at the output A₂, of the step-down converter 2′. Said output current I_out serves as operating current for all of the connected light-emitting diodes D_1, D_2, . . . D_N. In the present exemplary embodiment a number of N branches l1, l2, . . . lN each having a light-emitting diode D_1, D_2, . . . D_N are connected to the supply line l supplied with the output current I_out. Each branch l1, l2, . . . lN can be isolated from the supply line l via a switch Sw_1, Sw_2, Sw_i, . . . Sw_n.

If we now consider an individual branch li (i=1 . . . N) formed by the switch Sw_i and the light-emitting diode D_i:

The mean diode current <Id_i> through a light-emitting diode D_i is:
<Id_{—}i>=I_out*ton_{—}i/Td,
where ton_i is the switch-on time duration of the switch Sw_i and Td is the time difference between a first switching-on of the switch Sw_i and a second switching on of the switch Sw_i. In this case, the switch-on time ton_i may also be expressed as a multiple of the period Tₛ of the clock signal clock.

If it is assumed, then, that two or more switches Sw_1, Sw_2 . . . Sw_i, . . . Sw_N are never switched on simultaneously, the switch-on period duration Td results precisely from the sum of the switch-on duration ton_i of all the switches Sw_i:
Td=Σ_{i=1 . . . N}ton_{—}i=Σ_{i=1 . . . N}K_{—}i*Ts,
where K_i is the number of period durations Ts of the clock signal clock of the step-down converter 2′ which are predetermined by the logic circuit 1 in order to obtain the correct operation current Id_1, Id_2, . . . Id_N in the various branches l1, l2, . . . lN.

It is furthermore provided that the system can also dynamically change the reference voltage v_ref in order to obtain the desired mean operating current <Id_1>, <Id_2>, . . . <Id_N> in the light-emitting diodes D_1, D_2, . . . D_i, . . . D_N.

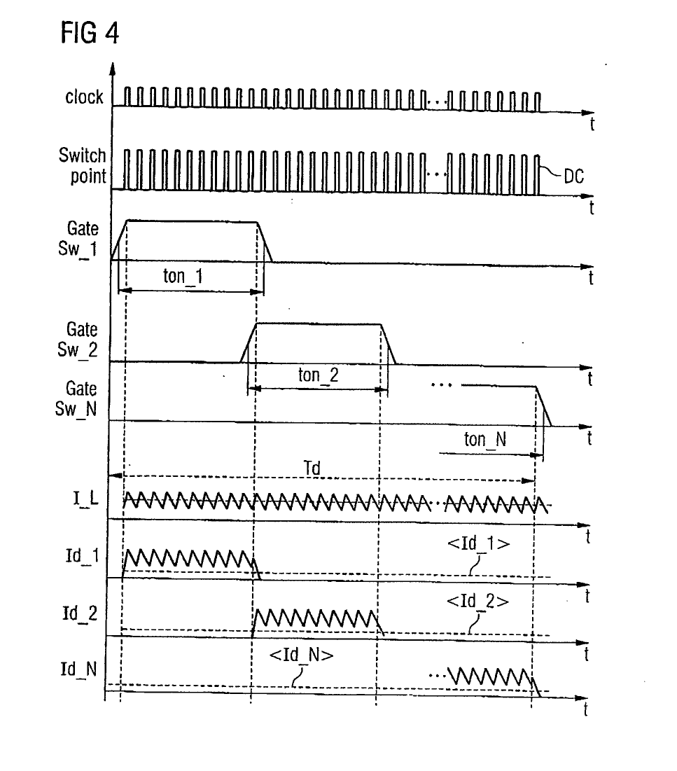

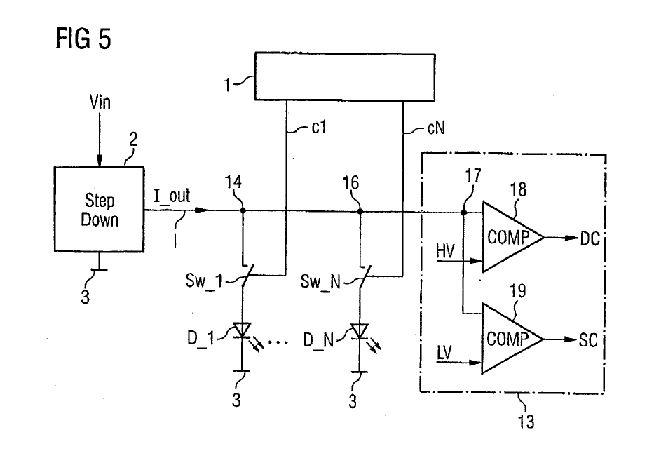

FIG. 4 shows by way of example the most important control and operating signals in the case of the circuit arrangement illustrated in FIG. 2. The topmost temporal signal profile represents the clock signal clock. Illustrated underneath is the switch point against time t, which switches on with the clock signal clock and switches off again after a time dependent on the regulating state (which corresponds to the lower signal in equivalence to FIG. 3). The three signal rows depicted underneath show the time durations ton_1, ton_2, . . . ton_N, during which the switches Sw_1, Sw_2, . . . Sw_N switch on the operating current Id_1, Id_2, . . . Id_N in the branches l1, l2, . . . lN to the light-emitting diodes D_1, D_2 . . . D_N (note: the switches Sw_1, Sw_2, . . . Sw_N are embodied as field effect transistors in the present exemplary embodiment. The switch-on times ton_1, ton_2, . . . ton_n therefore correspond to the gate driving signals Gate Sw_1, Gate Sw_2, . . . Gate Sw_N for the switches Sw_1, Sw_2, . . . Sw_N), the sum of which in the exemplary embodiment precisely produces the switch-on period duration Td. The sixth signal row shows the induction current I_L of the step-down converter 2′ with the characteristic saw-tooth-like temporal profile thereof about a mean value depicted in dashed fashion. The last three rows show the respective temporal profile of the operating currents Id_1, Id_2, . . . Id_N. During the respective switch-on time durations ton_1, ton_2, . . . ton_N of the corresponding switches Sw_1, Sw_2, . . . Sw_N, these operating currents Id_1, Id_2, . . . Id_N are identical to the output current Iout of the step-down converter 2′ and therefore essentially equal to the induction current I_L. The operating currents Id_1, Id_2, . . . Id_N are otherwise zero. A mean operating current <Id_1>, <Id_2>, . . . <Id_N> therefore results in the branches l1, l2, . . . lN. The mean operating currents <Id_1>, <Id_2>, . . . <Id_N> in the branches l1, l2, . . . lN are likewise depicted in dotted fashion in the lower three signal rows.

It is expressly pointed out once again that in this embodiment variant there is the possibility of setting different operating currents, Id_1, Id_2, . . . Id_N in the different branches l1, l2, . . . lN. The overall system can be adapted to different applications by merely altering the logic control 1 for the switches Sw_1, Sw_2, . . . Sw_N and, if appropriate dynamically, the desired (mean) induction current I_L (<I_L>).

1. A circuit arrangement, comprising:
a first switch device operably coupled to alternately switch on and off a first operating current to a first light-emitting diode arrangement such that the first light-emitting diode arrangement has a first brightness,
at least a second switch device operably coupled to alternately switch on and off a second operating current to at least a second light-emitting diode arrangement such that the second light-emitting diode arrangement has a second brightness,
a logic device configured to control the first and second switch devices that the first and second switch devices do not both switch on simultaneously.

2. The circuit arrangement as claimed in claim 1, further comprising a third switch operably coupled to alternately switch on and off a third operating current to a third light-emitting diode arrangement such that the third light-emitting diode arrangement has a third brightness, and wherein the logic device is designed to drive the third switch device such that the third switch does not switch on simultaneously with the first switch and does not switch on simultaneously with the second switch.

3. The circuit arrangement as claimed in claim 1, wherein the logic device is configured to drive the switch devices using periodic signals.

4. The circuit arrangement as claimed in claim 1, wherein the logic device is configured to drive of the switch devices using a predetermined mark-space ratio.

5. The circuit arrangement as claimed in claim 1, wherein the first light-emitting diode arrangement comprises at least one of the following group of arrangements: a single light-emitting diode, a parallel circuit formed by a plurality of light-emitting diodes and, a series circuit formed by a plurality of light-emitting diodes.

6. The circuit arrangement as claimed in claim 1, wherein the first switch device includes a transistor.

7. The circuit arrangement as claimed in claim 1, further comprising a current source configured to provide a total operating current for the first light-emitting diode arrangement and the second light-emitting diode arrangement.

8. The circuit arrangement as claimed in claim 7, wherein the current source comprises a constant-current source having a regulated output current.

9. The circuit arrangement as claimed in claim 8, wherein the current source comprises a switched-mode power supply.

10. The circuit arrangement as claimed in claim 1, further comprising an error identification circuit configured to identify an error in at least one of the light-emitting diode arrangements.

11. The circuit arrangement as claimed in claim 10, wherein the error identification circuit comprises an overvoltage identification device configured to identify an overvoltage in at least one of the light-emitting diode arrangements and/or an undervoltage identification device for identifying an undervoltage in at least one of the light-emitting diode arrangements.

12. A method for operating a first light-emitting diode arrangement and at least a second light-emitting diode arrangement, comprising:
a) alternately switching on and off a first operating current for the first light-emitting diode arrangement such that the first light-emitting diode arrangement has a first predetermined brightness, and
b) alternately switching on and off a second operating current for the second light-emitting diode arrangement such that the second light-emitting diode arrangement has a second predetermined brightness, wherein at least the first and the second light-emitting diode arrangements are not switched on simultaneously.

13. The method as claimed in claim 12, further comprising alternately switching on and off a plurality of other operating currents for a plurality of other light emitting diode arrangements, and wherein the operating currents of two or more light-emitting diode arrangements are not switched on simultaneously.

14. The method as claimed in claim 12, wherein step a) further comprises using a periodic clock to alternately switch on and off the first operating current.

15. The method as claimed in claim 12, wherein the operating currents of the light-emitting diode arrangements are switched on with a predetermined mark-space ratio.

16. The method as claimed in claim 12, wherein the first light-emitting diode arrangement comprises at least one of the following group of arrangements: a single light-emitting diode, a parallel circuit formed by a plurality of light-emitting diodes, and a series circuit formed by a plurality of light-emitting diodes.

17. The method as claimed in one of claim 12, further comprising:
providing a total operating current for the first light-emitting diode arrangement and the second light-emitting diode arrangement using a single current source.

18. The method as claimed in claim 17, wherein providing the total operating current further comprises providing the total operating current as a regulated total operating current.

19. The method as claimed in claim 18, wherein the total operating current is dynamically adapted to a respective current demand such that a predetermined brightness of each light-emitting diode arrangement is obtained.

20. The method as claimed in claim 12, further comprising:
performing a check in at least the first light-emitting diode arrangement to determine whether an error has occurred.

21. A circuit arrangement, comprising:
a first switch device operably coupled to alternately switch on and off a first operating current to the first light-emitting diode arrangement such that the first light-emitting diode arrangement has a first predetermined brightness,
at least a second switch device operably coupled to alternately switch on and off a second operating current to the second light-emitting diode arrangement such that the second light-emitting diode arrangement has a second predetermined brightness, and
a logic device configured to control the first and second switch devices that the first and second switch devices do not both switch on simultaneously.
